(19) United States
(12) Patent Application Publication
(10) Pub. No.: US 2026/0090055 A1
(43) Pub. Date: Mar. 26, 2026

(54) SEMICONDUCTOR DEVICE AND FABRICATION METHOD THEREOF

(71) Applicant: Vanguard International semiconductor Corporation, Hsinchu (TW)

(72) Inventors: Wen-Shan Lee, Hsinchu City (TW); Chung-Yeh Lee, Hsinchu County (TW); Fu-Hsin Chen, Hsinchu County (TW)

(73) Assignee: Vanguard International Semiconductor Corporation, Hsinchu (TW)

(21) Appl. No.: 18/890,783

(22) Filed: Sep. 20, 2024

(51) Int. Cl. H01L 29/417; H01L 27/06; H01L 29/40; H01L 29/66; H01L 29/739

(52) U.S. Cl. CPC H10D 64/231; H10D 12/035; H10D 12/038; H10D 12/481; H10D 64/117; H10D 84/617

(57) ABSTRACT

A semiconductor device includes a structure layer having a first surface opposite to a second surface. A collector region is disposed in the structure layer and located on the first surface. An emitter region is disposed in the structure layer and located on the second surface. A first trench is disposed in the structure layer and extends downward from the first surface into the emitter region. A gate electrode is disposed in the first trench. A second trench is laterally separated from the first trench. An emitter contact is disposed in the second trench and extends downward into the emitter region. An emitter electrode is disposed under the second surface and in direct contact with the emitter region. A collector electrode is disposed above the first surface and electrically connected to the collector region.

### BACKGROUND OF THE INVENTION

### 1. Field of the Invention

The present disclosure relates generally to semiconductor technology, and more particularly to a semiconductor device including a reverse conducting insulated gate bipolar transistor and a fabrication method thereof.

### 2. Description of the Prior Art

An insulated gate bipolar transistor (IGBT) is a power semiconductor component, which has an input terminal structure constructed by a metal-oxide-semiconductor field effect transistor (MOSFET), and an output terminal structure constructed by a bipolar junction transistor (BJT). The IGBT has three terminals of a gate, a collector and an emitter. The gate is the same as that of the MOSFET, and the collector and the emitter are the same as those of the BJT. The IGBT combines the characteristics of low driving current of the MOSFET and low on-state resistance of the BJT, and is suitable for high voltage and fast switching speed applications. The IGBT is a unipolar component without a reverse conducting (RC) ability, and an anti-parallel diode is required for protection in most circuits applying the IGBT. A reverse conducting insulated gate bipolar transistor (RC-IGBT) is a semiconductor component that integrates an IGBT and a freewheeling diode (FWD) on a single chip, where the FWD and the IGBT are connected in anti-parallel. The FWD allows the current to flow from the emitter to the collector in the RC-IGBT, thereby avoiding voltage surges. Although the RC-IGBT has many advantages, the conventional RC-IGBTs still cannot fully satisfy various requirements in applications.

### SUMMARY OF THE INVENTION

In view of this, the present disclosure provides a semiconductor device and a fabrication method thereof, which simplifies the back-end process of a reverse conducting insulated gate bipolar transistor (RC-IGBT) by modifying the structures of a gate, a collector, and an emitter. Therefore, the production yield of the semiconductor device is improved. Moreover, the reverse recovery charge (Qrr) and the gate-to-collector charge (Qgc) of the semiconductor device are both reduced, thereby reducing the switch loss and the power dissipation. Therefore, the electrical performances of the semiconductor device are enhanced.

According to an embodiment of the present disclosure, a semiconductor device is provided and includes a structure layer, a collector region, an emitter region, a first trench, a gate electrode, a second trench, an emitter contact, an emitter electrode, and a collector electrode. The structure layer has a first surface opposite to a second surface. The collector region having a first conductivity type is disposed in the structure layer and located on the first surface. The emitter region having a second conductivity type is disposed in the structure layer and located on the second surface. The first trench is disposed in the structure layer and extends downward from the first surface into the emitter region. The gate electrode is disposed in the first trench. The second trench is disposed in the structure layer and laterally separated from the first trench. The emitter contact is disposed in the second trench and extends downward into the emitter region. The emitter electrode is disposed under the second surface of the structure layer and in direct contact with the emitter region. The collector electrode is disposed above the first surface of the structure layer and electrically connected to the collector region.

According to an embodiment of the present disclosure, a method of fabricating a semiconductor device is provided and includes the following steps. A structure layer is provided and includes a first epitaxial layer and a second epitaxial layer formed on an emitter region in sequence from bottom to top. The first epitaxial layer has a first conductivity type, and both the emitter region and the second epitaxial layer have a second conductivity type. A collector region is formed in the second epitaxial layer and has the first conductivity type. A first trench is formed in the structure layer, penetrates the collector region, the second epitaxial layer and the first epitaxial layer, and extends downward into the emitter region. A gate electrode is formed in the first trench. A second trench is formed in the structure layer, penetrates the second epitaxial layer, and extends downward into the first epitaxial layer. An emitter contact is formed in the second trench and extends downward into the emitter region. A collector electrode is formed above the second epitaxial layer and electrically connected to the collector region. In addition, an emitter electrode is formed under the emitter region and in direct contact with the emitter region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor device according to an embodiment of the present disclosure.

FIG. 2, FIG. 3, FIG. 4, FIG. 5, FIG. 6, FIG. 7, FIG. 8, FIG. 9 and FIG. 10 are schematic cross-sectional views of some stages of a method of fabricating a semiconductor device according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure relates to a semiconductor device including a reverse conducting insulated gate bipolar transistor (RC-IGBT) and a fabrication method thereof. In some embodiments, a collector region, a heavily doped region and a buffer region are all disposed on a first surface (such as a front side) of a structure layer and at a collector terminal. An emitter region is disposed on a second surface (such as a back side) of the structure layer and at an emitter terminal. The collector region has a first conductivity type, for example, a p-type heavily doped collector region. The heavily doped region has a second conductivity type, for example, an n-type heavily doped region. The buffer region has the second conductivity type, for example, an n-type buffer region. The emitter region has the second conductivity type, for example, an n-type heavily doped emitter region. In addition, a first trench is formed in the structure layer and extends downward from the first surface into the emitter region. A gate electrode is disposed in the first trench, so that the semiconductor device has an emitter-down and gate-down structure. According to the embodiments, multiple ion implantation processes required to fabricate the RC-IGBT are completed on the front side of the structure layer, thereby simplifying the back-end process of the semiconductor device. Furthermore, a shield electrode may be disposed above the gate electrode in the first trench, thereby reducing the gate-to-collector charge (Qgc). Moreover, the composition of the structure layer may be silicon carbide to reduce the reverse recovery charge (Qrr), thereby significantly reducing the switching loss and the power consumption of the semiconductor devices. Therefore, the semiconductor devices of the present disclosure are suitable for applications in high voltage and fast switching speed.

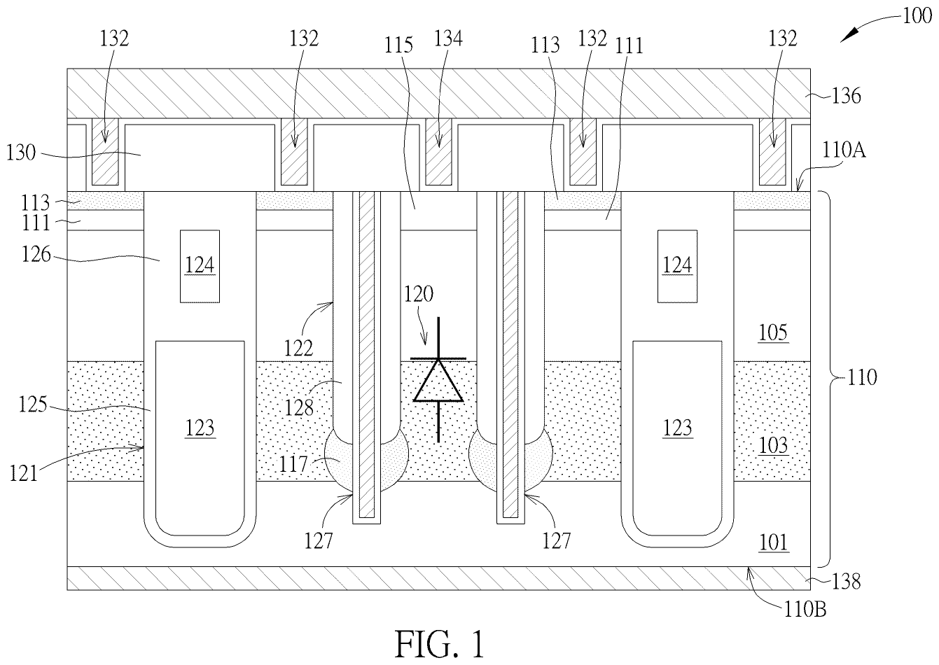

FIG. 1 is a schematic cross-sectional view of a semiconductor device 100 according to an embodiment of the present disclosure. The semiconductor device 100 includes a structure layer 110 having a first surface 110A such as the front side opposite to a second surface 110B such as the back side. In addition, the structure layer 110 includes an emitter region 101, a first epitaxial layer 103 and a second epitaxial layer 105. The first epitaxial layer 103 and the second epitaxial layer 105 are stacked and grown on the emitter region 101 in sequence from bottom to top, and the first epitaxial layer 103 is in direct contact with the emitter region 101. The first epitaxial layer 103 has the first conductivity type such as a p-type epitaxial layer, and both the emitter region 101 and the second epitaxial layer 105 have the second conductivity type. The emitter region 101 is, for example, an n-type heavily doped (N⁺) region and located on the second surface 110B of the structure layer. The second epitaxial layer 105 is, for example, an n-type lightly doped (N⁻) epitaxial layer. In some embodiments, the emitter region 101, the first epitaxial layer 103 and the second epitaxial layer 105 may be composed of silicon or silicon carbide (SiC), but not limited thereto. When the structure layer 110 is composed of silicon carbide, the semiconductor device 100 can withstand high voltages even the overall thickness of the structure layer 110 is decreased. For example, when the structure layer 110 is composed of silicon carbide and the overall thickness thereof is about 5 μm to about 10 μm, the semiconductor device 100 can withstand voltages of at least 600V.

The semiconductor device 100 further includes a collector region 113, a heavily doped region 115 and a buffer region 111 disposed in the structure layer 110 and all located on the first surface 110A of the structure layer. The collector region 113 has the first conductivity type such as a p-type heavily doped collector region (P⁺-Collector), the buffer region 111 has the second conductivity type such as an n-type buffer region (N-Buffer), and the heavily doped region 115 has the second conductivity type such as an n-type heavily doped (N⁺) region. The doping concentration of the collector region 113 is higher than that of the buffer region 111. The doping concentration of the heavily doped region 115 is higher than that of the second epitaxial layer 105. In one embodiment, the doping concentration of the heavily doped region 115 may also be higher than that of the buffer region 111. In addition, the buffer region 111 is located between the collector region 113 and the second epitaxial layer 105. The buffer region 111 may be used as a field stop layer to reduce the electric field intensity around the collector region 113, thereby producing a more uniform electric field distribution between the second epitaxial layer 105 and the collector region 113 to maintain a higher breakdown voltage. Moreover, the buffer region 111 reduces both the switching loss and the voltage drop, which is beneficial to the applications in high speed switching. In one embodiment, the buffer region 111 is disposed directly below both the collector region 113 and the heavily doped region 115. The bottom surface of the heavily doped region 115 may be level with or lower than the top surface of the buffer region 111. In another embodiment, the buffer region 111 is disposed directly below the collector region 113. The bottom surface of the heavily doped region 115 and the bottom surface of the buffer region 111 are on the same plane, and the heavily doped region 115 is in direct contact with the second epitaxial layer 105.

In addition, the semiconductor device 100 includes a first trench 121 disposed in the structure layer 110 and extending downward from the first surface 110A to the emitter region 101. The bottom surface of the first trench 121 is lower than the top surface of the emitter region 101. Both the collector region 113 and the buffer region 111 are located on opposite sides of the first trench 121. As shown in FIG. 1, the collector region 113 has two portions located on opposite sides of the first trench 121, and the buffer region 111 also has two portions located on opposite sides of the first trench 121. A gate electrode 123 and a shield electrode 124 are disposed in the first trench 121. The shield electrode 124 is located directly above the gate electrode 123 and vertically separated from the gate electrode 123. A first dielectric layer 125 and a second dielectric layer 126 are also disposed in the first trench 121. The first dielectric layer 125 surrounds the side and bottom surfaces of the gate electrode 123 to be a gate dielectric layer. The second dielectric layer 126 surrounds the side and bottom surfaces of the shield electrode 124 and separates the shield electrode 124 from the gate electrode 123. The thickness of the second dielectric layer 126 is greater than the thickness of the first dielectric layer 125 to provide a good electrical isolation.

As shown in FIG. 1, the semiconductor device 100 further includes a second trench 122 disposed in the structure layer 110 and extending downward from the first surface 110A to the first epitaxial layer 103. The second trench 122 is laterally separated from the first trench 121. The bottom surface of the second trench 122 is located in the first epitaxial layer 103, and the bottom surface of the first trench 121 is lower than the bottom surface of the second trench 122. In one embodiment, both the collector region 113 and the buffer region 111 are located on a first side of the second trench 122, and the heavily doped region 115 is located on an opposite second side of the second trench 122. In another embodiment, the buffer region 111 may be further disposed on the second side of the second trench 122 and directly below the heavily doped region 115. In addition, a body region 117 is disposed directly below the second trench 122 and extends downward to contact the emitter region 101. The body region 117 has the first conductivity type such as a p-type heavily doped body region (P⁺-body). An emitter contact 127 is disposed in the second trench 122, extends downward from the first surface 110A, and penetrates the bottom surface of the second trench 122 and the body region 117 into the emitter region 101. The emitter contact 127 is in direct contact with the body region 117 and the emitter region 101. A third dielectric layer 128 is also disposed in the second trench 122 and surrounds the side surface of the emitter contact 127. The thickness of the third dielectric layer 128 is greater than the thickness of the first dielectric layer 125. The third dielectric layer 128 provides a good electrical isolation between the emitter contact 127 and the second epitaxial layer 105 and between the emitter contact 127 and the first epitaxial layer 103.

In addition, an interlayer dielectric (ILD) layer 130 is disposed on the first surface 110A of the structure layer, and has multiple openings to expose the collector region 113 and the heavily doped region 115. A collector contact 132 is disposed in one opening of the ILD layer 130 to be in direct contact with the collector region 113. A contact plug 134 is disposed in another opening of the ILD layer 130 to be in direct contact with the heavily doped region 115. A collector electrode 136 is located above the first surface 110A of the structure layer and disposed on the ILD layer 130. The collector region 113 is electrically connected to the collector electrode 136 through the collector contact 132. The heavily doped region 115 is electrically connected to the collector electrode 136 through the contact plug 134. An emitter electrode 138 is disposed under the second surface 110B of the structure layer to be in direct contact with the emitter region 101.

In the semiconductor device 100, the gate electrode 123, the collector electrode 136 and the emitter electrode 138 constitute an insulated gate bipolar transistor (IGBT), and the first epitaxial layer 103 and the second epitaxial layer 105 constitute a freewheeling diode (FWD) 120. The current of the IGBT flows from the collector electrode 136 to the emitter electrode 138. The current of the FWD 120 flows from the emitter electrode 138, passes through the first epitaxial layer 103, the second epitaxial layer 105 and the heavily doped region 115 and flows to the collector electrode 136. Accordingly, the FWD 120 and the IGBT are connected in anti-parallel to constitute a reverse conducting insulated gate bipolar transistor (RC-IGBT).

Furthermore, the semiconductor device 100 includes a gate pad, a collector pad and an emitter pad (as shown in FIG. 10). All of these pads are disposed above the first surface 110A of the structure layer. The gate electrode 123 is electrically coupled to the gate pad. The emitter contact 127 and the shield electrode 124 are both electrically coupled to the emitter pad. The collector electrode 136 is in direct contact with the collector pad.

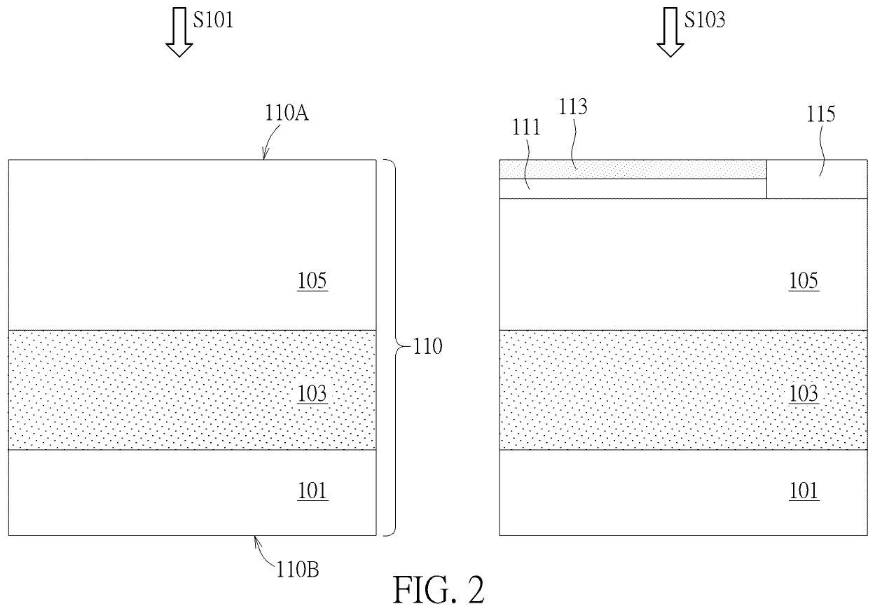

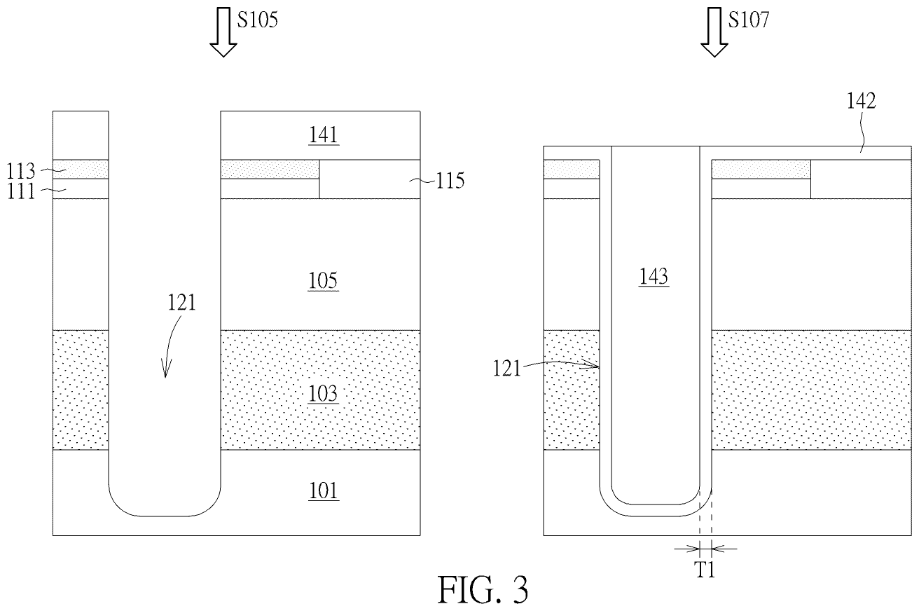

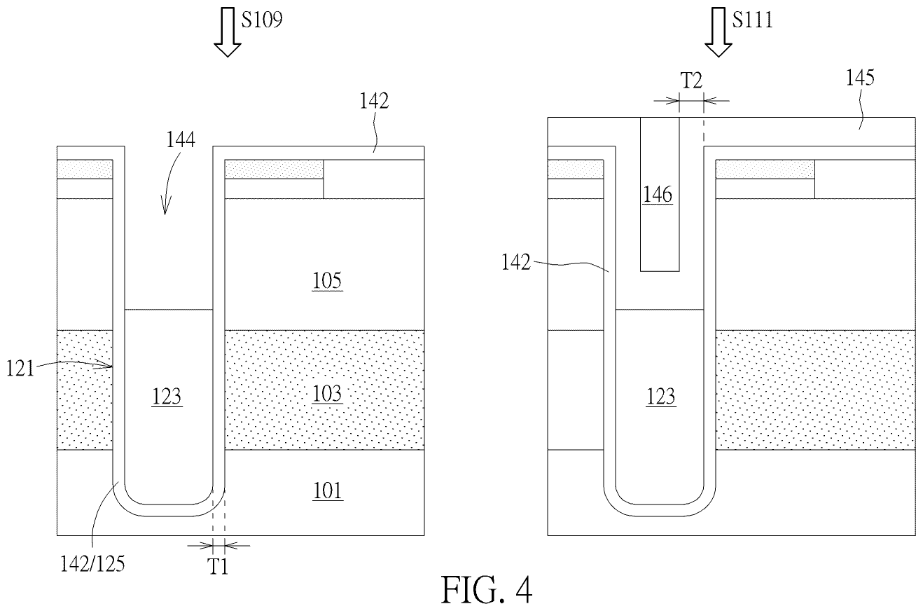

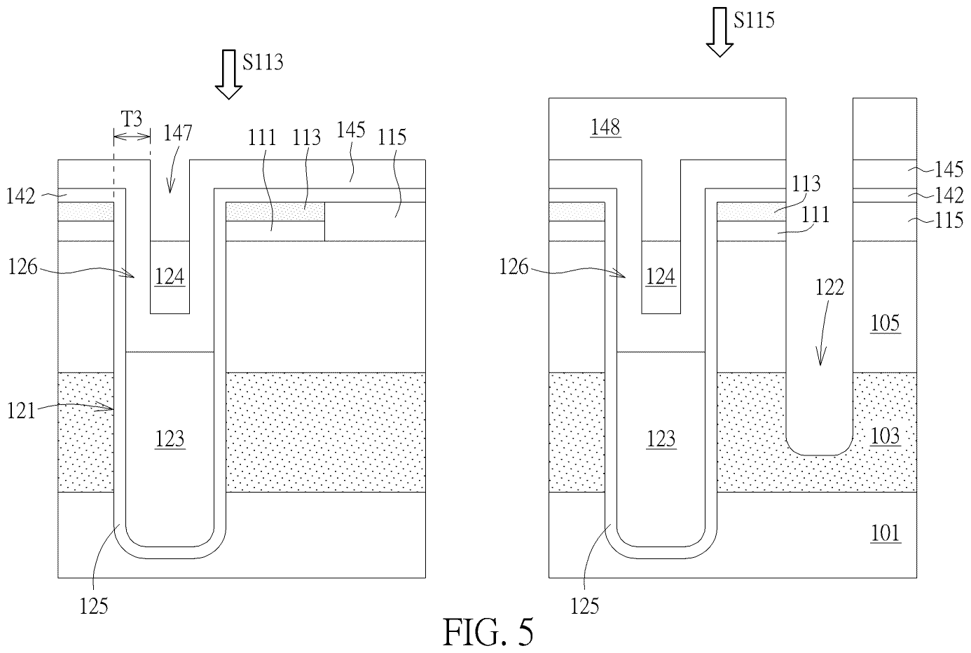

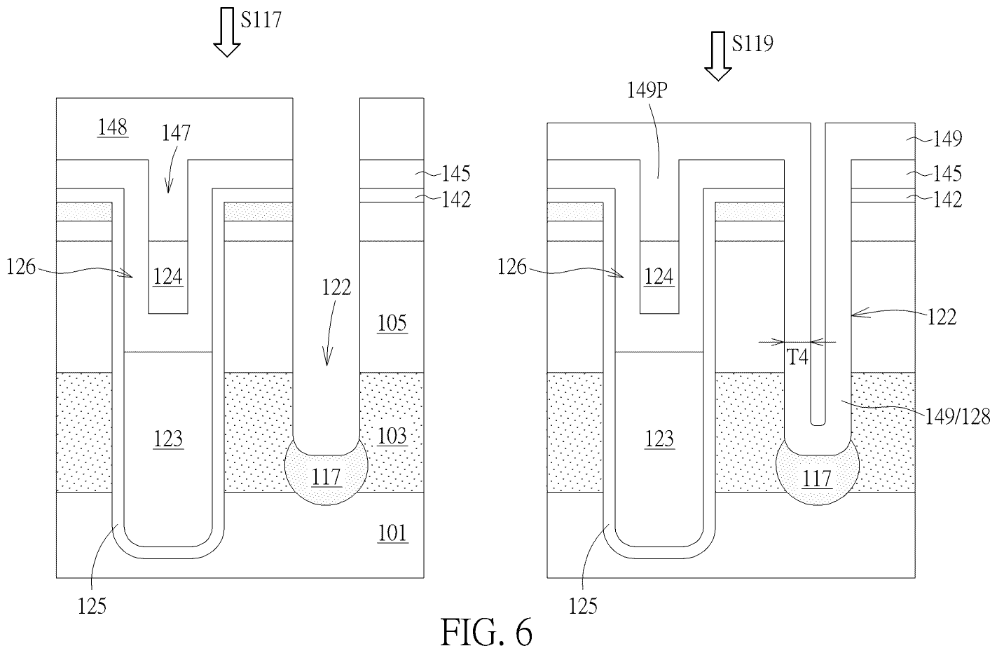

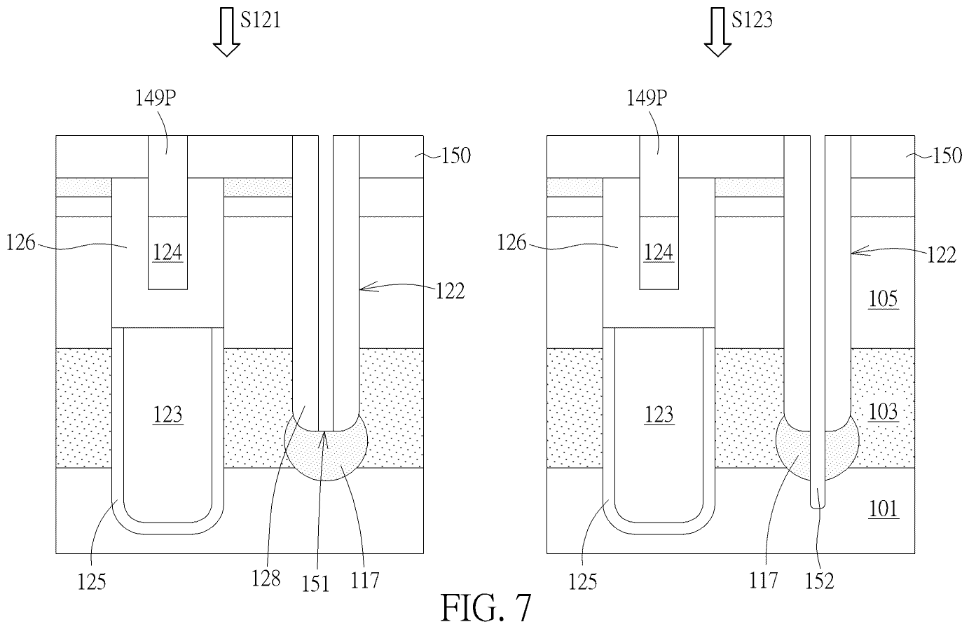

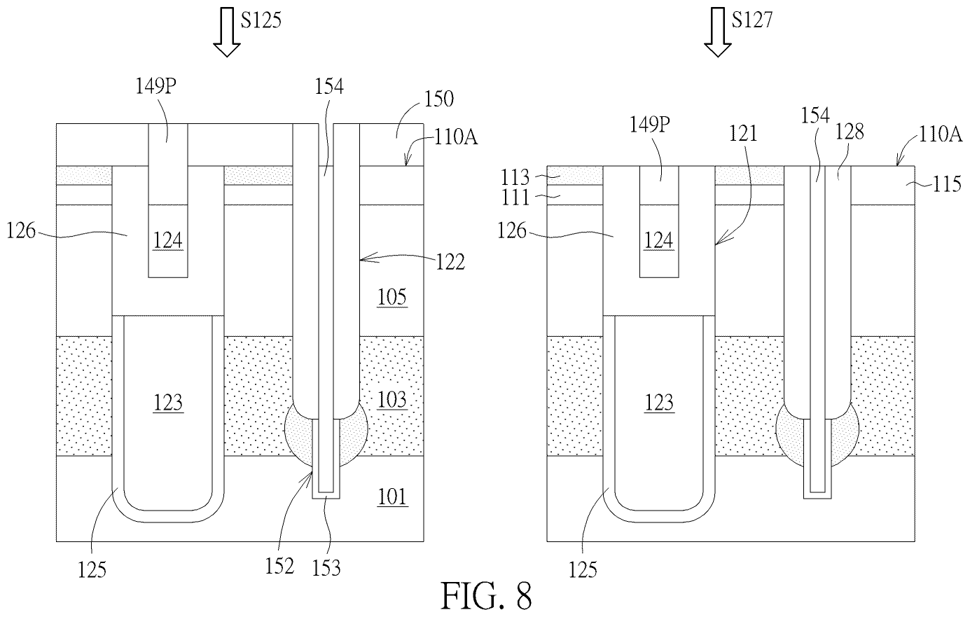

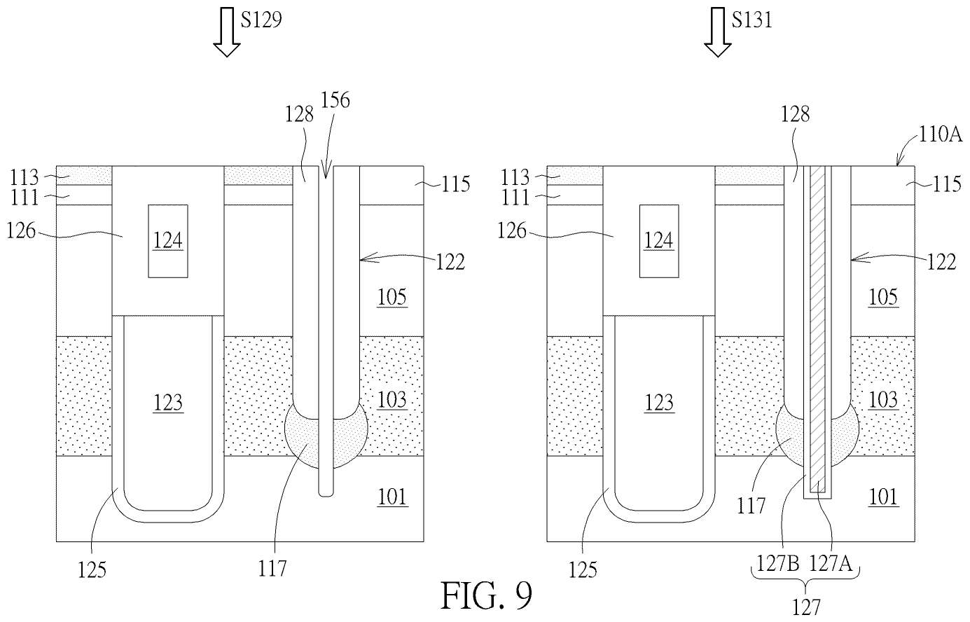

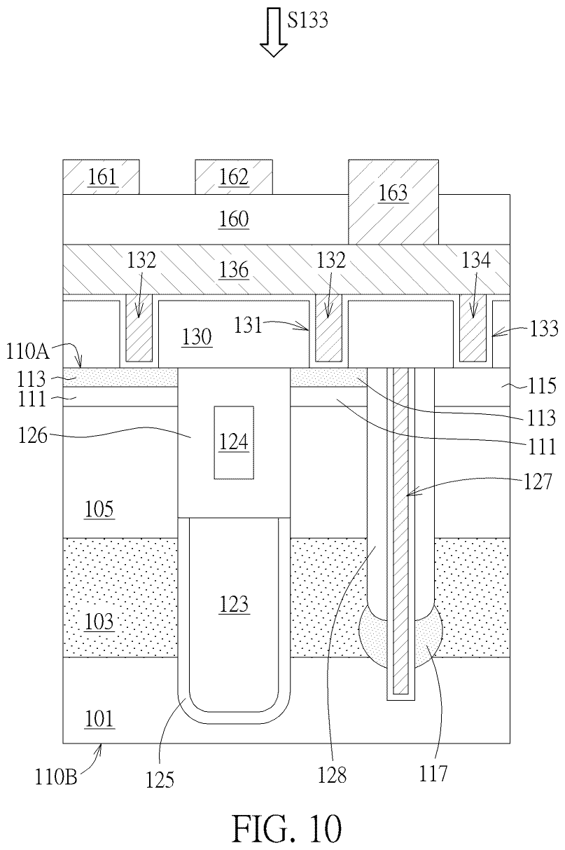

FIG. 2, FIG. 3, FIG. 4, FIG. 5, FIG. 6, FIG. 7, FIG. 8, FIG. 9 and FIG. 10 are schematic cross-sectional views of some stages of a method of fabricating a semiconductor device 100 according to an embodiment of the present disclosure. Referring to FIG. 2, in step S101, firstly, a structure layer 110 is provided, which includes a first epitaxial layer 103 and a second epitaxial layer 105 grown on an emitter region 101 in sequence from bottom to top. The structure layer 110 has a first surface 110A opposite to a second surface 110B. The first epitaxial layer 103 has the first conductivity type, and both the emitter region 101 and the second epitaxial layer 105 have the second conductivity type. In one embodiment, the emitter region 101 is, for example, an n-type heavily doped silicon carbide (N⁺-SiC) substrate, and the doping concentration of the emitter region 101 is, for example, about 1E19 to 2E20 atoms/cm³. The first epitaxial layer 103 is, for example, a p-type silicon carbide (P-SiC) epitaxial layer, and the doping concentration of the first epitaxial layer 103 is, for example, about 1E15 to 1E18 atoms/cm³. The second epitaxial layer 105 is, for example, an n-type lightly doped silicon carbide (N⁻SiC) epitaxial layer, and the doping concentration of the second epitaxial layer 105 is, for example, about 1E15 to 1E18 atoms/cm³. The overall thickness of the epitaxial layers in the structure layer is, for example, about 5 μm to about 10 μm, but not limited thereto.

Still referring to FIG. 2, in step S103, a buffer region 111 is formed in the second epitaxial layer 105 by using a patterned mask such as a patterned photoresist layer and an ion implantation process on the first surface 110A of the structure layer 110. The buffer region 111 has the second conductivity type such as an n-type buffer region, and the doping concentration of the buffer region 111 is, for example, about 1E15 to 1E18 atoms/cm³. The top surface of the buffer region 111 is lower than the top surface of the second epitaxial layer 105. Then, a collector region 113 is formed in the second epitaxial layer 105 by using another patterned mask and another ion implantation process on the first surface 110A of the structure layer 110. The collector region 113 has the first conductivity type such as a p-type heavily doped region, and the doping concentration of the collector region 113 is, for example, about 1E19 to 2E20 atoms/cm³. The collector region 113 is located directly above the buffer region 111, and the bottom surface of the collector region 113 is in direct contact with the top surface of the buffer region 111.

Next, a heavily doped region 115 is formed in the second epitaxial layer 105 by using another patterned mask and another ion implantation process on the first surface 110A of the structure layer 110. The heavily doped region 115 has the second conductivity type such as an n-type heavily doped region, and the doping concentration of the heavily doped region 115 is higher than that of the second epitaxial layer 105. Moreover, the doping concentration of the heavily doped region 115 may be higher than that of the buffer region 111. The doping concentration of the heavily doped region 115 is, for example, about 1E15 to 5E18 atoms/cm³. In step S103, the heavily doped region 115 laterally abuts the collector region 113. In one embodiment, the heavily doped region 115 may be located above the buffer region 111, and the bottom surface of the heavily doped region 115 is in direct contact with the top surface of the buffer region 111. In another embodiment, the bottom surface of the heavily doped region 115 may be lower than the top surface of the buffer region 111 and located in the buffer region 111. In further another embodiment, the bottom surface of the heavily doped region 115 may be level with the bottom surface of the buffer region 111 and in direct contact with the second epitaxial layer 105.

Referring to FIG. 3, in step S105, a first trench 121 is formed in the structure layer 110 by an etching process and using a patterned hard mask 141. The first trench 121 penetrates the collector region 113, the buffer region 111, the second epitaxial layer 105 and the first epitaxial layer 103 and extends downward from the first surface 110A into the emitter region 101. In step S105, firstly, a hard mask material layer is deposited on the first surface 110A of the structure layer 110, and then the hard mask material layer is patterned by photolithography and etching processes to form the patterned hard mask 141. Through the opening of the patterned hard mask 141, the etching process is performed on the structure layer 110 to form the first trench 121. Afterwards, the patterned hard mask 141 is removed. In one embodiment, a sacrificial oxide layer may be formed in the first trench 121 and then removed to repair the surface damage caused by the etching process of forming the first trench 121. Then, a high-temperature process may be used to activate the dopants in the collector region 113, the heavily doped region 115, and the buffer region 111.

Still referring to FIG. 3, in step S107, a dielectric material layer 142 is conformally formed in the first trench 121 and on the first surface 110A of the structure layer 110 by a thermal oxidation or a deposition process. The dielectric material layer 142 has a first thickness T1 and is composed of, for example, silicon oxide. Then, a semiconductor material layer 143 is deposited on the first surface 110A of the structure layer 110 and to fill up the first trench 121 by a deposition process. During this deposition process, dopants with a conductivity type may be added to form a doped semiconductor material layer such as a doped polysilicon layer. Afterwards, the semiconductor material layer located on the top surface of the dielectric material layer 142 is removed by a chemical mechanical planarization (CMP) process, so that the top surface of the semiconductor material layer 143 in the first trench 121 is level with the top surface of the dielectric material layer 142.

Referring to FIG. 4, in step S109, an upper portion of the semiconductor material layer 143 is removed by an etch-back process, thereby forming a gate electrode 123 and a recess 144 in the first trench 121. The dielectric material layer 142 in the first trench 121 forms a first dielectric layer 125 to surround the side and bottom surfaces of the gate electrode 123, and the first dielectric layer 125 has the first thickness T1. In one embodiment, the top surface of the gate electrode 123 is higher than the top surface of the first epitaxial layer 103, and the bottom surface of the gate electrode 123 is lower than the top surface of the emitter region 101.

Still referring to FIG. 4, in step S111, a dielectric material layer 145 is conformally formed in the recess 144 and on the first surface 110A of the structure layer 110 by a deposition process. The dielectric material layer 145 covers the dielectric material layer 142 and the gate electrode 123. The dielectric material layer 145 is composed of, for example, silicon oxide and has a second thickness T2 greater than the first thickness T1. Next, a semiconductor material layer 146 is deposited on the first surface 110A of the structure layer 110 and to fill up the first trench 121 by a deposition process. During this deposition process, dopants with a conductivity type may be added to form a doped semiconductor material layer, for example, a doped polysilicon layer. Then, the semiconductor material layer located on the top surface of the dielectric material layer 145 is removed by a CMP process, so that the top surface of the remaining semiconductor material layer 146 is level with the top surface of the dielectric material layer 145.

Referring to FIG. 5, in step S113, an upper portion of the semiconductor material layer 146 is removed by an etch-back process, thereby forming a shield electrode 124 and a recess 147 in the first trench 121. Both the dielectric material layer 142 and the dielectric material layer 145 in the first trench 121 form a second dielectric layer 126 to surround the side and bottom surfaces of the shield electrode 124. The second dielectric layer 126 is located above the gate electrode 123 to vertically separate the shield electrode 124 from the gate electrode 123. The second dielectric layer 126 has a third thickness T3 that is the sum of the first thickness T1 and the second thickness T2.

Still referring to FIG. 5, in step S115, a patterned photoresist layer 148 is formed on the first surface 110A of the structure layer 110 and fills up the recess 147 by a photolithography process. Next, an etching process is performed on the structure layer 110 through the opening of the patterned photoresist layer 148 to form a second trench 122 penetrating the collector region 113, the buffer region 111, the heavily doped region 115 and the second epitaxial layer 105. The second trench 122 extends downward from the first surface 110A into the first epitaxial layer 103. The bottom surface of the second trench 122 is higher than the top surface of the emitter region 101 and lower than the top surface of the first epitaxial layer 103.

Referring to FIG. 6, in step S117, a body region 117 is formed directly below the second trench 122 by an ion implantation process. The body region 117 has the first conductivity type such as a p-type heavily doped body region (P⁺-body). The doping concentration of the body region 117 is, for example, about 1E19 to 2E20 atoms/cm³. The body region 117 is located in the first epitaxial layer 103 and extends downward to contact the emitter region 101. The bottom surface of the body region 117 may be located in the emitter region 101. Afterwards, the patterned photoresist layer 148 is removed.

Still referring to FIG. 6, in step S119, a dielectric material layer 149 is conformally formed in the second trench 122 and on the first surface 110A of the structure layer 110 by a deposition process. The dielectric material layer 149 has a fourth thickness T4, and is composed of, for example, silicon oxide. The dielectric material layer 149 located in the second trench 122 forms a third dielectric layer 128 having the fourth thickness T4 that is greater than the first thickness T1 and approximately equal to the third thickness T3. Moreover, the dielectric material layer 149 covers the dielectric material layer 145, and a portion 149P of the dielectric material layer 149 fills up the recess 147 that is left after the patterned photoresist layer 148 is removed.

Referring to FIG. 7, in step S121, a portion of the third dielectric layer 128 located on the bottom surface of the second trench 122 is removed by an etching process such as an anisotropic dry etching process, thereby forming a third opening 151 to expose the body region 117. Meanwhile, the thickness of the dielectric material layer 149 located on the dielectric material layer 145 is also reduced. The dielectric material layer 145, the dielectric material layer 142 and the remaining dielectric material layer 149 constitute a dielectric material layer 150. Still referring to FIG. 7, in step S123, a portion of the body region 117 exposed by the third opening 151 is etched by another etching process, and the etching is further downward into the emitter region 101 to form a sub-trench 152. The sub-trench 152 is located directly below the second trench 122 and exposes the body region 117 and the emitter region 101.

Referring to FIG. 8, in step S125, an oxide liner layer 153 is conformally formed on the side and bottom surfaces of the sub-trench 152 by a thermal oxidation process. The oxide liner layer 153 is, for example, a silicon oxide layer, and covers the exposed surfaces of the body region 117 and the emitter region 101. Next, a protective material 154 is deposited on the dielectric material layer 150 and fills up the remaining spaces of the second trench 122 and the sub-trench 152 by a deposition process. The composition of the protective material 154 is, for example, silicon nitride. The oxide liner layer 153 may be a stress buffer layer to disperse the stress generated by filling the sub-trench 152 with the protective material 154, thereby protecting the body region 117 and the emitter region 101. Thereafter, the protective material 154 on the dielectric material layer 150 is removed by an etch-back process, so that the top surface of the protective material 154 in the second trench 122 and the first surface 110A of the structure layer 110 are substantially on the same plane.

Still referring to FIG. 8, in step S127, the dielectric material layer 150 on the first surface 110A is removed by a CMP process, so that the second dielectric layer 126 filling in the first trench 121, the top surface of the portion 149P of the dielectric material layer, the third dielectric layer 128 filling in the second trench 122, the top surface of the protective material 154, and the first surface 110A of the structure layer 110 are on the same plane.

Referring to FIG. 9, in step S129, the protective material 154 in the second trench 122 and the sub-trench 152 is removed by a stripping process, and then the oxide liner layer 153 in the sub-trench 152 is removed by using a diluted hydrofluoric acid (DHF) solution, thereby forming a fourth opening 156. The fourth opening 156 is located in the second trench 122 and extends downward into the emitter region 101 to expose the body region 117 and the emitter region 101. Still referring to FIG. 9, in step S131, a diffusion barrier material layer is conformally formed on the first surface 110A of the structure layer 110 and in the fourth opening 156 by a deposition process. The composition of the diffusion barrier material layer is, for example, titanium (Ti), titanium nitride (TiN), tantalum (Ta), tantalum nitride (TaN), zirconium nitride (ZrN) or other suitable diffusion barrier materials. In one embodiment, a rapid thermal annealing process may be used to form a silicide such as titanium silicide (TiSix) between the diffusion barrier material layer and the body region 117, and also between the diffusion barrier material layer and the emitter region 101, thereby reducing the contact resistance between a subsequently formed emitter contact 127 and the body region 117, and the contact resistance between the emitter contact 127 and the emitter region 101.

Afterwards, a conductive material is deposited on the first surface 110A of the structure layer 110 and fills up the fourth opening 156 by a deposition process. The conductive material is, for example, tungsten (W), copper (Cu) or other suitable metals. Then, the conductive material and the diffusion barrier material layer on the first surface 110A of the structure layer 110 are removed by an etch-back process to form the emitter contact 127 that includes a diffusion barrier layer 127B and a conductive portion 127A. The emitter contact 127 is located in the second trench 122, extends downward from the first surface 110A of the structure layer 110, and penetrates the body region 117 into the emitter region 101. The third dielectric layer 128 in the second trench 122 surrounds a partial side surface of the emitter contact 127. A portion of the emitter contact 127 is in direct contact with the body region 117 and the emitter region 101.

Referring to FIG. 10, in step S133, an interlayer dielectric (ILD) layer 130 is formed completely on the first surface 110A of the structure layer 110 and located above the second epitaxial layer 105 by a deposition process. Then, a first opening 131 and a second opening 133 are formed in the ILD layer 130 by photolithography and etching processes, where the first opening 131 exposes the collector region 113 and the second opening 133 exposes the heavily doped region 115. Next, a diffusion barrier layer is conformally formed on the ILD layer 130 and in the first opening 131 and the second opening 133 by a deposition process. Thereafter, the first opening 131 and the second opening 133 are filled with a conductive material, such as tungsten (W), copper (Cu) or other suitable metals, by another deposition process, thereby forming a collector contact 132 and a contact plug 134 to contact with the collector region 113 and the heavily doped region 115, respectively. Afterwards, a first metal layer is formed on the ILD layer 130 by a deposition process and a patterning process, thereby forming a collector electrode 136. The composition of the collector electrode 136 is, for example, aluminum copper (AlCu) or other suitable metal materials. The collector electrode 136 is connected to the collector contact 132 and the contact plug 134. Moreover, the collector electrode 136 is located above the second epitaxial layer 105, electrically coupled to the collector region 115 through the collector contact 132, and electrically coupled to the heavily doped region 115 through the contact plug 134.

Next, a passivation layer 160 is formed on the collector electrode 136 by a deposition process. The composition of the passivation layer 160 is, for example, silicon oxide, silicon nitride, silicon oxynitride or a combination thereof. Then, an opening is formed in the passivation layer 160 by photolithography and etching processes to expose the collector electrode 136. Thereafter, an emitter pad 161 and a gate pad 162 are formed on the passivation layer 160, and a collector pad 163 is formed in the opening of the passivation layer 160 by a deposition process and a patterning process. The gate electrode 123 is electrically coupled to the gate pad 162 through vias and wire layers (not shown). The emitter contact 127 and the shield electrode 124 are electrically coupled to the emitter pad 161 through other vias and wire layers (not shown). The collector electrode 136 may be in direct contact with the collector pad 163. Afterwards, in the back-end process, a second metal layer is deposited on the second surface 110B of the structure layer 110 by a deposition process to form an emitter electrode 138 (as shown in FIG. 1), which is composed of, for example, aluminum copper (AlCu) or other suitable metal materials. The emitter electrode 138 is located under and in direct contact with the emitter region 101. Thereafter, the fabrication of the semiconductor device 100 is completed.

According to some embodiments of the present disclosure, all the ion implantation processes required for fabricating the RC-IGBT are completed on the first surface (the front side) of the structure layer, thereby forming the doped regions such as the collector region, the buffer region and the heavily doped region. Therefore, after the backside grinding and metallization processes on the second surface (the back side) of the structure layer are completed, there is no need to perform additional ion implantation and laser annealing processes. Accordingly, the back-end process is simplified and the process complexity is reduced, thereby enhancing the production yield of the semiconductor device.

Moreover, the composition of the structure layer may be silicon carbide. When the overall thickness of the structure layer is reduced, the semiconductor device can still withstand high voltage. Accordingly, the depths of the first trench and the second trench may be decreased to reduce the process difficulty of forming these trenches. In addition, the gate electrode in the first trench and the emitter contact in the second trench are close to the emitter region, thereby forming the emitter-down and gate-down structure, which allows the emitter region and the emitter electrode of the RC-IGBT to be disposed on the second surface (the back side) of the structure layer.

Furthermore, the semiconductor device of the present disclosure can reduce the reverse recovery charge (Qrr) and the gate-to-collector charge (Qgc), thereby significantly reducing the switching loss and the power consumption. Therefore, the electrical performances of the semiconductor device are improved and suitable for the applications in high-voltage and high speed switching. Moreover, in the embodiments of the present disclosure, the gate pad, the collector pad and the emitter pad are all disposed on the first surface (the front side) of the structure layer. Accordingly, the semiconductor devices of the present disclosure are easily integrated with other low voltage components and power components such as transistors fabricated by Bipolar-CMOS-DMOS (BCD) process in a monolithic chip, thereby improving the industrial utilization.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a structure layer, having a first surface and a second surface opposite to each other;
a collector region, having a first conductivity type, disposed in the structure layer and located on the first surface;
an emitter region, having a second conductivity type, disposed in the structure layer and located on the second surface;
a first trench, disposed in the structure layer and extending downward from the first surface into the emitter region;
a gate electrode, disposed in the first trench;
a second trench, disposed in the structure layer and laterally separated from the first trench;
an emitter contact, disposed in the second trench and extending downward into the emitter region;
an emitter electrode, disposed under the second surface of the structure layer and in direct contact with the emitter region; and
a collector electrode, disposed above the first surface of the structure layer and electrically connected to the collector region.

2. The semiconductor device of claim 1, further comprising a heavily doped region having the second conductivity type, disposed in the structure layer, located on the first surface, and electrically connected to the collector electrode.

3. The semiconductor device of claim 1, wherein the structure layer comprises:
a first epitaxial layer, having the first conductivity type, disposed on and in direct contact with the emitter region; and
a second epitaxial layer, having the second conductivity type, disposed on and in direct contact with the first epitaxial layer, wherein the first epitaxial layer and the second epitaxial layer constitute a freewheeling diode.

4. The semiconductor device of claim 3, wherein the gate electrode, the collector electrode and the emitter electrode constitute an insulated gate bipolar transistor, and the freewheeling diode is connected in anti-parallel to the insulated gate bipolar transistor.

5. The semiconductor device of claim 3, wherein a bottom surface of the first trench is lower than a bottom surface of the second trench, and the bottom surface of the second trench is located in the first epitaxial layer.

6. The semiconductor device of claim 3, further comprising a buffer region having the second conductivity type, disposed directly below the collector region, and located between the collector region and the second epitaxial layer.

7. The semiconductor device of claim 6, wherein both the collector region and the buffer region are located on opposite sides of the first trench.

8. The semiconductor device of claim 6, wherein both the collector region and the buffer region are located on a first side of the second trench, and the heavily doped region is located on a second side of the second trench.

9. The semiconductor device of claim 1, further comprising a body region, having the first conductivity type, disposed directly below the second trench, and extending downward to contact the emitter region, wherein the emitter contact penetrates the body region and is in direct contact with the body region and the emitter region.

10. The semiconductor device of claim 1, further comprising:
a shield electrode, disposed in the first trench, located directly above the gate electrode, and vertically separated from the gate electrode;
a first dielectric layer, disposed in the first trench and surrounding a side surface and a bottom surface of the gate electrode; and
a second dielectric layer, disposed in the first trench and surrounding a side surface and a bottom surface of the shield electrode, wherein a thickness of the second dielectric layer is greater than a thickness of the first dielectric layer.

11. The semiconductor device of claim 10, further comprising a gate pad, a collector pad and an emitter pad all disposed above the first surface of the structure layer, wherein the gate electrode is electrically coupled to the gate pad, both the emitter contact and the shield electrode are electrically coupled to the emitter pad, and the collector electrode is in direct contact with the collector pad.

12. The semiconductor device of claim 10, further comprising:
a third dielectric layer, disposed in the second trench and surrounding a side surface of the emitter contact, wherein a thickness of the third dielectric layer is greater than the thickness of the first dielectric layer.

13. A method of fabricating a semiconductor device, comprising:
providing a structure layer comprising an emitter region, a first epitaxial layer and a second epitaxial layer, wherein the first epitaxial layer and the second epitaxial layer are formed on the emitter region in sequence from bottom to top, the first epitaxial layer has a first conductivity type, and both the emitter region and the second epitaxial layer have a second conductivity type;
forming a collector region in the second epitaxial layer, wherein the collector region has the first conductivity type;
forming a first trench in the structure layer, penetrating the collector region, the second epitaxial layer and the first epitaxial layer, and extending downward into the emitter region;
forming a gate electrode in the first trench;
forming a second trench in the structure layer, penetrating the second epitaxial layer, and extending downward into the first epitaxial layer;
forming an emitter contact in the second trench and extending downward into the emitter region;
forming a collector electrode above the second epitaxial layer and electrically connected to the collector region; and
forming an emitter electrode under the emitter region and in direct contact with the emitter region.

14. The method of claim 13, further comprising:
forming a buffer region in the second epitaxial layer before forming the collector region, wherein the buffer region has the second conductivity type; and
forming a heavily doped region in the second epitaxial layer after forming the collector region, wherein the heavily doped region has the second conductivity type, and a doping concentration of the heavily doped region is higher than that of the second epitaxial layer,
wherein the collector region is located directly above the buffer region, and the heavily doped region laterally abuts the collector region before forming the second trench.

15. The method of claim 14, wherein the first trench penetrates the collector region and the buffer region, and the second trench penetrates the heavily doped region, the collector region and the buffer region.

16. The method of claim 14, further comprising:
forming an interlayer dielectric layer on the second epitaxial layer;
forming a first opening in the interlayer dielectric layer to expose the collector region;
forming a second opening in the interlayer dielectric layer to expose the heavily doped region;
filling the first opening and the second opening with a conductive material to form a collector contact and a contact plug to contact with the collector region and the heavily doped region, respectively; and
forming a first metal layer on the interlayer dielectric layer and connecting to the collector contact and the contact plug to form the collector electrode.

17. The method of claim 13, further comprising:
conformally forming a first dielectric layer in the first trench to surround a side surface and a bottom surface of the gate electrode;
conformally forming a second dielectric layer in the first trench and above the gate electrode, wherein a thickness of the second dielectric layer is greater than a thickness of the first dielectric layer; and
forming a shield electrode in the first trench, wherein the second dielectric layer surrounds a side surface and a bottom surface of the shield electrode.

18. The method of claim 17, further comprising:
forming a passivation layer above the collector electrode;
forming a gate pad and an emitter pad on the passivation layer;
forming a collector pad in the passivation layer; and
depositing a second metal layer under the emitter region to form the emitter electrode,
wherein the gate electrode is electrically coupled to the gate pad, both the emitter contact and the shield electrode are electrically coupled to the emitter pad, and the collector electrode is in direct contact with the collector pad.

19. The method of claim 17, further comprising:
forming a body region directly below the second trench after forming the second trench, wherein the body region has the first conductivity type, is located in the first epitaxial layer and contacts with the emitter region; and
conformally forming a third dielectric layer in the second trench, wherein a thickness of the third dielectric layer is greater than the thickness of the first dielectric layer.

20. The method of claim 19, wherein forming the emitter contact comprises:
removing a portion of the third dielectric layer located on a bottom surface of the second trench to form a third opening to expose the body region;
etching a portion of the body region exposed by the third opening, and etching downward into the emitter region to form a sub-trench directly below the second trench;
forming an oxide liner layer on a side surface and a bottom surface of the sub-trench;
filling the second trench and the sub-trench with a protective material;
removing the protective material and the oxide liner layer to form a fourth opening; and
filling the fourth opening with a conductive material to form the emitter contact, wherein the third dielectric layer surrounds a side surface of the emitter contact.
